(19) United States
(12) Patent Application Publication
(10) Pub. No.: US 2010/0271119 A1
(43) Pub. Date: Oct. 28, 2010

(54) ENVELOPE DETECTOR, LINEARIZATION CIRCUIT, AMPLIFIER CIRCUIT, METHOD FOR DETECTING A MODULATION ENVELOPE AND WIRELESS COMMUNICATION UNIT

(76) Inventors: Walid Karoui, Toulouse (FR); Rachid Jaoui, Plaisance du touch (FR); Pierre Savary, Muret (FR); Thierry Parra, Toulouse (FR)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/446,921

(22) PCT Filed: Oct. 23, 2006
(86) PCT No.: PCT/IB06/54688

§ 371 Date: Dec. 1, 2009

(51) Int. Cl. H03D 3/00

(52) U.S. Cl. 329/345

(57) ABSTRACT

An envelope (100) detector for detecting a modulation envelope of a modulated signal. The envelope detector includes a sensor (102). The sensor has a sensor input (1021), for sensing a signal forming a measure for the amount of electrical power presented at the sensor input (1021). The sensor input (1021) is electrically conducting connectable to an electrical path (14), along which electrical path (14) the modulated signal is transmitted. The detector (100) includes a filter (103) for removing from the sensed signal a part contributed to non-envelope signal components in the modulated signal; and a detector output (104) connected to the filter (103) for outputting an envelope signal.

### FIELD OF THE INVENTION

This invention relates to, an envelope detector, an amplifier circuit, a wireless communication unit and a method for detecting a modulation envelope.

### BACKGROUND OF THE INVENTION

Amplifiers are generally known in the art. For example, power amplifiers are widely used in wireless transmission systems to amplify a signal such that the signal has sufficient energy to be transmitted via an antenna. However, often the performance is limited by the non-linear behaviour of the Power Amplifier (PA). To obviate the non-linear behaviour of the PA, various techniques are known, such as predistortion and envelope injection techniques.

For example Chi-Shuen et al. “A New Approach to Amplifier Linearization by the Generalized Baseband Signal Injection Method”, IEEE Microwave and Wireless Components Letters, VOL. 12, N^{o} 9, pp 336-338. September 1999 discloses a circuit which determines a base-band signal from an input signal, and injects the base-band signal into a power amplifier. The circuit further injects the base-band signal into a diode predistorter, which is connected to the amplifier as well. The circuit includes a coupler by means of which a combined capacitive and inductive connection to a signal path is established, in order to receive the input signal. The coupler is connected to the gate of a MESFET, which acts as a low frequency detector. The output of the MESFET is transmitted to respective operational amplifiers (opamps). Each of the opamps provides an amplified signal to a corresponding quarter wavelength phase-shifter. The quarter wavelength phase shifters are connected to the diode predistorter and the amplifier, respectively.

However, a disadvantage of this circuit is that it consumes a significant amount of power and leads to a trade off between linearity and power added efficiency (PAE). Furthermore, it is difficult to implement as an integrated circuit, because the operational amplifiers are typically manufactured with a different kind of process than the power amplifier. Also, the circuit has a large footprint because the coupler occupies a large amount of space.

### SUMMARY OF THE INVENTION

The present invention provides an envelope detector, a linearization circuit, an amplifier circuit, a wireless communication unit and a method for detecting a modulation envelope as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings.

FIG. 1 shows a block diagram of a first example of an embodiment of an amplifier circuit

FIG. 2 shows a block diagram of a second example of an embodiment of an amplifier circuit.

FIG. 3| shows a block diagram of an example of an embodiment of a wireless communication unit.

FIGS. 4-XX show graphs of simulated amplitudes as a function of time at different nodes in the example of FIG. 2

### DETAILED DESCRIPTION OF THE PREFERRED EMBODIMENTS

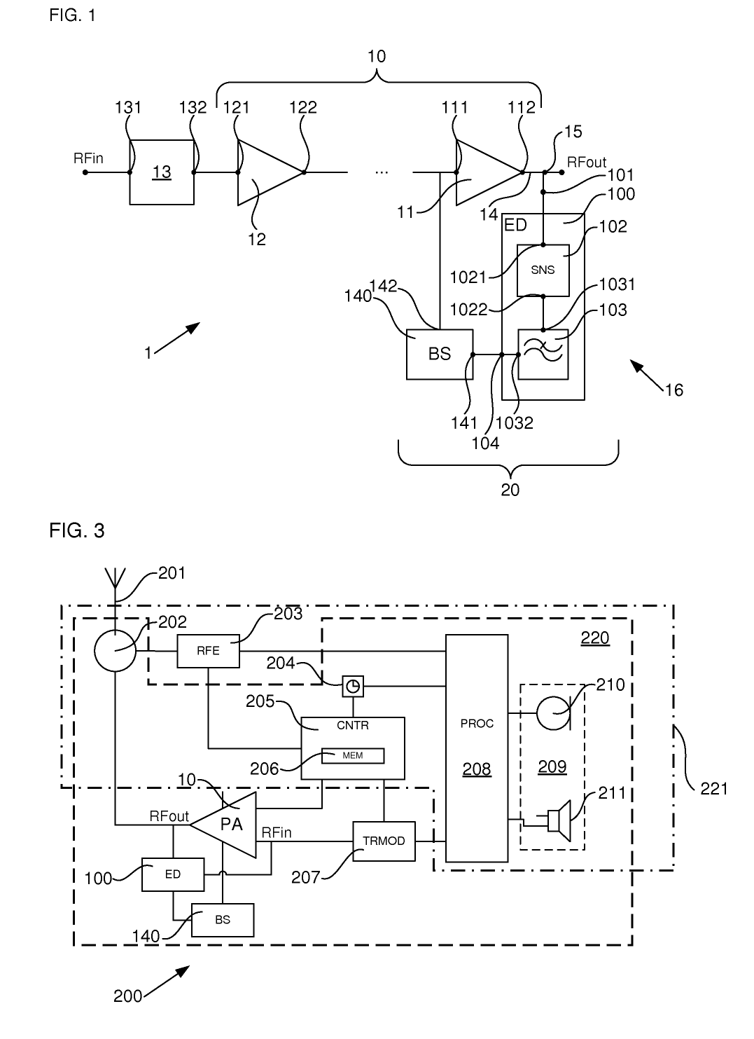

Although in the following an example of an embodiment will be described which forms an amplifier circuit, it should be noted that the invention may be implemented in any other type of electronic circuit and the invention is not limited to applications in amplifier circuits. Referring to FIG. 1, as shown therein by way of example, an amplifier circuit 1 may include a power amplifier (PA) 10 with one or more amplifier stages 11-12 and may include one or more preceding stages 13 positioned upstream of the power amplifier 10. The amplifier circuit 1 further may include a bias source 140 and a linearization circuit or linearizer 16. The amplifier circuit 1 may process a modulated signal and, for example output a modulated signal via an electrical path 14.

The linearizer 16 may, as shown in FIG. 1, include an envelope detector 100. The envelope detector 100 can detect a modulation envelope of the modulated signal and output an envelope signal which represents the modulation envelope. The envelope detector 100 may, as shown in FIG. 1, for instance include a detector input 101, a power sensor (SNS) 102, a filter 103, and a detector output 104. As shown in the example of FIG. 1, the sensor 102 may include a sensor input 1021 and a sensor output 1022. The sensor input 1021 may be connected to the envelope detector input 101. The sensor output 1022 of the sensor 102 may be connected to a filter input 1031. The filter 103 may be connected with a filter output 1032 to the envelope detector output 104.

The envelope detector 100 may operate as follows. The sensor 102 may sense a parameter which forms a measure for the amount of electrical power presented at the sensor input 1021. The sensor 102 may for example sense the current transmitted along an electrical path 14 to which the sensor input 101 is connected via an electrically conducting connection. As for instance shown in the example of FIG. 1, the sensor input 1021 is connected via an electrically conducting connection to a node 15 of an electrical path 14 along which a modulated signal may be transmitted. The sensor 102 may output a signal representing the sensed parameter to the filter 103. The filter 103 may remove a part of the frequency components present in the sensed signal, resulting in an envelope signal. The part may for example be at least a part of the components with frequencies different from the frequencies of the signal envelope. The filter 103 may subsequently output at the envelope detector output 104 the envelope signal.

As shown in the example of FIG. 1, the envelope detector 100 does not have a coupler. Accordingly, the footprint of the envelope detector 100 may be reduced, and implementation of the envelope detector 100 in an integrated circuit may be less complex. Also, the envelope detector 100 may be implemented without operational amplifiers, and hence be implemented in the same integrated circuit as, for example, the amplifier 10.

The sensor 102 may be implemented in any manner suitable for the specific implementation. The sensor 102 may generate, from the inputted signal, a signal which can be inputted in the filter 103 and which includes information about the envelope of the modulated signal.

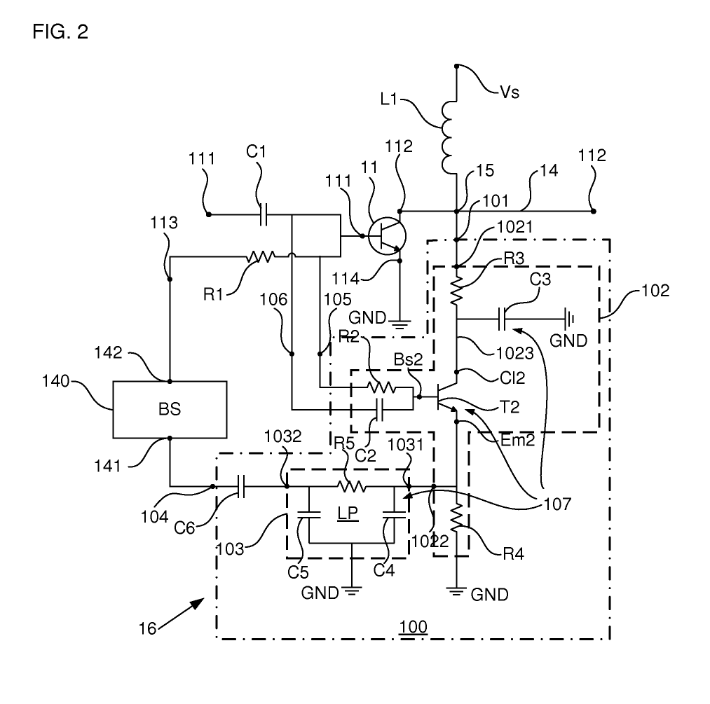

The sensor 102 may for example include a current sensor for sensing the amount of current flowing through the electrical path 14. The amplifier may have for example a current output. Without wishing to be bound to any theory, since for a current output the voltage at the current output is constant, e.g. determined by the power source Vs of the amplifier, the current forms a measure for the outputted amount of power. To sense the current, the sensor 102 may for example be connected with the sensor input 1021 to a node 15 of the electrical path 14, and a part of the electrical power flowing through the electrical path 14 may be fed to the sensor 102 via the sensor input 1021. Referring to the example shown in FIG. 2, the envelope detector 100 may for example include an electrical conducting path 1023 between the node 15 and the sensor 102. An image signal, for instance an image current, may be fed into the sensor 102 via the electrical conducting path 1023.

For instance, in the example of FIG. 2, the sensor 102 includes an active electrical device T2 which generates a current signal which is an image of the power amplifier output signal. That is, the current signal has substantially the same frequency characteristics as the signal sensed at the sensor input 1021, i.e. as the modulated signal. However, the current signal may for example differ in amplitude compared to the modulated signal. The current signal may be very small compared to the modulated signal. For example, the current signal may have a current amplitude which is less than 1% of the amplitude of the modulated signal, for example 0.25% or less, such as 0.1% or less. For instance, a ratio of the power of the current signal relative to the power of the modulated signal which allows an accurate determination of the envelope signal without significant changes in the output of the amplifier is found to be 0.01 dB or less.

The active electrical device T2 be any suitable type of device. The active electrical device may for example include an controllable current source which is connected with a current input to the electrical path 14, such as a bipolar transistor (BT) such as a Heterojunction Bipolar Transistor (HBT), a field effect transistor or other controllable current source. The active electric device may for example be of a type similar to an active device which outputs the modulated signal. For example, as shown in FIG. 2, the active electric device may be a transistor in case the active device is a transistor and be the same type of transistor as the device that outputs the modulated signal, e.g. in the example of FIG. 2, the PA transistor 11.

As shown in FIG. 2, an electrically conducting path 1023 may be present between a device terminal Cl2 of the active electrical device T2 and the electrical path 14. Via the device terminal Cl2, the active device T2 may draw a part of the current into the sensor 102, which part is proportional to the current flowing through the electrical path 14. The active electrical device T2 may have another device terminal for outputting the current signal. As shown in FIG. 2, the active device T2 may for instance output the current signal at a current output Em2. The current output Em2 may, for example, be directly connected to a filter input 1031 of the filter 103. However, the output may also be connected indirectly to the filter input 1031. The sensor 102 for instance may include a current-to-voltage converter R4 which connects the current output Em2 to the filter input 1031 and converts the current into a voltage in order to input the voltage into a device downstream of the current-to-voltage converter, e.g. into a voltage filter 103 which removes from a voltage signal components of undesired frequencies.

The sensor 102 may include a current control input 106 at which a signal may be presented which controls the current drawn by the active device source. As for instance shown in the example of FIG. 2, the active electrical device T2 may have an amplitude control input Bs2 at which an amplitude control signal may be inputted. The current control input 106 may be connected to the amplitude control input Bs2, which in the example of FIG. 2 is formed by a base of the HBT.

The amplitude control signal may for example be the same signal as an input signal presented to a device to which the modulated signal is presented or by which the modulated signal is outputted. As is explained below in more detail, for example, the amplitude control signal may be a modulated signal inputted to an amplifier 10, or other device, to which the envelope signal is inputted, be processed, e.g. amplified, together with the modulated signal. Thereby, the modulation distortion incurred in the electronic device due to non-linear behaviour can be reduced.

The active electrical device T2 may be arranged to control at least the amplitude of the current signal based on the amplitude control signal. In case, as for instance shown in FIG. 2, the active electrical device includes a transistor, such as a BT, a HBT for example, the current flowing through the transistor, e.g. from the collector of the BT to the emitter, is proportional to the voltage applied at the amplifier control input, e.g. at the base of the BT. The transistor, e.g. the BT in FIG. 2, may for example be operated in the linear region and output a current at the emitter which is linearly dependent on the voltage provided at the base.

As shown in FIG. 2, the active electrical device T2 may have a bias input connected to a sensor bias input 105. At the bias input, a bias signal may be inputted. The bias signal may for example be the same bias signal as the bias signal presented to a device to which the modulated signal is presented or by which the modulated signal is outputted. As for instance shown in the example of FIG. 2, the active electrical device T2 may include a BT, a HBT for example, which is connected with its base to the sensor bias control input 105.

The sensor 102 may as shown in FIG. 2 include a voltage output 1022 for outputting a voltage proportional to the sensed amount of current. To generate this voltage, the sensor 102 may for example include a current-to-voltage converter R4 which converts the amount of current flowing through the active device T2 into a voltage. The converter R4 may convert the current signal into a voltage signal and input the voltage signal into the filter 103. In the example of FIG. 2, for instance, the sensor 102 includes a current path between the sensor input 101 and a current-to-voltage converter R4. Via the current path, a current signal representing the signal sensed at the sensor input 1021 may be sent to the converter R4. The current-to-voltage converter R4 may, as shown in FIG. 2, consist of a single resistor, however, the current-to-voltage converter R4 may be implemented with more components. In the example of FIG. 2, the resistor R4 connects the active device T2 to ground GND or other reference voltage. Since the voltage over the resistor R4 is proportional to the current flowing through the resistor R4, the current signal can be converted into a voltage signal.

The envelope detector 100 may consist of passive components and transistors only. Thereby, the envelope detector 100 may be especially suited for implementation in a single integrated circuit. Furthermore, the components of the envelope detector 100 may be manufactured in the same process as an amplifier, and accordingly may thereby be implemented in the same integrated circuit as the amplifier 10. As for example shown in FIG. 2, the envelope detector 100 may consist of transistors, resistors and capacitors only.

Between sensor input 1021 and the active device T2, a power limiter may be present. The power limiter may limit the amount of power inputted to the sensor 102, to prevent a power overload of the components in the sensor 102. For example, in case the sensor 102 includes an active device T2, operation of the active device T2 in a desired region may be ensured. For example, in case the active device T2 includes a BT, such as a HBT, the collector current Ic may degrade when the amount of power transmitted over the electrical path 14, and hence the sensed signal, exceeds a threshold. For example, without wishing to be bound to any theory, it has been found that at a Power Amplifier output power of 15 dBm or more the collector current of a HBT might deteriorate due to the negative swing of the collector current.

The power limiter may for example an RC network between the sensor 102 and the detector input 101. For instance in the example of FIG. 2, a resistor R3 connects an input Cl2 to the envelope detector input 101. A capacitor C3 connects a node between the resistor R3 and the active device T2 to ground. The RC network reduces the RF swing and especially the negative swing at the part indicated with reference sign 1023 in FIG. 2. The RC circuit may have a time-constant τ which is smaller than the inverse of the carrier frequency f_{carrier}, that is τ<1/f_{carrier}. The resistor R3 may for example have an impedance which is (much) higher than the output impedance downstream of the path 14 in order to minimize the leakage of power via the envelope detector 100.

The envelope detector 100 may include a phase shifter for shifting the phase of the envelope signal relative to the modulated signal. The envelope detector 100 may include a phase shifter 107 The phase shifter 107 may, for example, shift the phase of the sensed signal or the envelope modulation signal, for example to have the envelope modulation signal match phase requirements imposed by the application of the envelope detector 100. For instance, as explained below in more detail the envelope detector may be used to reduce inter modulation distortion (IMD) by injecting the envelope signal into a device which processes the modulated signal, and the phase shifter may adjust the phase of the respective signal to ensure that the injected envelope signal has a phase which reduces the distortion components in the signal.

The phase shifter may be implemented in any manner suitable for the specific implementation. In the example of FIG. 2, for instance, the phase shifter 107 may for example include the filter 103 and/or the RC network R3/C3 and/or the capacitance present in the active device T2. The phase shifter 107 may be present between the sensor input 1021 and the filter output 1032. The phase shifter may be included in components of the envelope detector performing other functions as well, such as in the example of FIG. 2, in the filter, the RC circuit or the active device T2. Thereby a reduction of the number of components in the circuit is enabled.

The filter 103 may be implemented in any manner suitable for the specific implementation. The filter may be connected with a filter input 1031 to the sensor 102, to receive the sensed signal. The filter 103 may remove from the sensed signal undesired signal components, and more in particular remove RF frequency components not included in the modulation envelope of the signal. The filter 103 may for instance remove components such as the carrier or other non-envelope components such as intermodulation products from the sensed signal. The filter 103 may for example include a low-pass filter. The filter 103 may for example be an active filter or be a passive filter, such as a LC filter or, as for instance in the example of FIG. 2, an RC filter. The filter 103 may for example be a first-order filter, a second order filter or a higher order filter.

The passive, low-pass filter may for example include a series RC-circuit which low-pass filters a voltage signal presented at a filter input 1031. The low-pass filter may have a cut-off frequency below the carrier frequency of the modulated signal and above the frequency fₑₙᵥ of the modulation envelope. For example, without wishing to be bound to any theory the low-pass filter is found to effectively function with fₑₙᵥ<f_{cut-off}<N·fₑₙᵥ and N being equal or larger than 3. For example, the cut-off frequency may be equal or larger than 200 KHz, such as 1.1 MHz or more, for example 4 MHz or more. the cut-off frequency may be lower than 2 GHz, such as lower than 800 KHz for example. As shown in FIG. 2, the filter may be connected with a filter output 1032 to the detector output 104. The filtered signal may be outputted via the filter output 1032 to the detector output 104 and be presented to another device, e.g. a bias source 140.

The envelope detector 100 may output the modulation envelope signal at an output 104 to other device. The output 104 may be connected to a capacitor C6 which reduces the DC level of the signal provided to the output 104. For example, the capacitor C6 may remove the DC off-set caused by the filter 103 such that the signal presented at the output 104 has a DC level of about zero.

The envelope detector 100 may be provided in any suitable device, for example in a demodulator or other suitable device. As shown in FIGS. 1 and 2, the envelope detector 100 may for example be present in a device, e.g. a power amplifier, and be connected with the detector output 104 to a node in the signal path of the device. The detector 100 may feed the envelope signal to the node and cause the generation of intermodulation products (IMD) components that at least partially cancel the inherent IMD components that are produced by the device due to the device input signal and the inherent non-linearity of the device. Thereby the out-of-band emissions may be reduced. The IMD components caused by the envelope signal may for example be in anti-phase (out of phase) with the inherent IMD components of the amplifier. The IMD components caused by the envelope signal may for example have substantially the same magnitude as the inherent IMD components.

As shown in FIGS. 1 and 2, the envelope detector 100 may for example be connected to a bias source 140 and feed, for example, the envelope signal into the bias source 140. The bias source 140 may be connected to a device to which the bias source provides a bias signal. Thereby, for example, a bias signal can be generated which causes a device to generate an intermodulation distortion reducing signal that at least partially reduces the inherent intermodulation distortion components of the electronic device, e.g. the power amplifier (PA). The electronic device may for example be an active device such as a Low Noise Amplifier (LNA), a mixer, a down converter, an up converters or a frequency multipliers.

In the example of FIG. 1, the envelope detector is connected to a bias source which provides a bias to the output stage 11. However, the envelope signal may in addition, or alternatively, be inputted at other positions in the amplifier circuit 10, for example in a stage 12,13 upstream of the output stage 11 to cause the amplifier circuit to generate signal components that at least partially cancel inherent distortion components generated in the circuit. Thereby, the linearity of the amplifier circuit may be improved.

The device may for example be an amplifier 10. The amplifier 10 may be any suitable type of amplifier. The amplifier 10 may for example be a power amplifier, such as an RF power amplifier. As shown in the example of FIG. 1, the amplifier 10 may have one or more amplifier stages 11,12. The amplifier stages 11,12 may have an amplifier stage input, and one or more amplifier stage outputs. For instance, the amplifier 10 may have an input stage 12 which drives a stage downstream of the input stage, such as an output stage 11. The input stage 12 may for example include a differential amplifier stage. As shown in FIG. 1, the amplifier circuit 1 may include one or more preceding stages 13, which are positioned upstream of the actual amplifier 10. The preceding stages 13 may for example a pre-distortion stage or other suitable type of stage. In the example of FIG. 1, an input 131 of the most upstream stage 13 is connected to an input RFin of the amplifier circuit 1. An output 132 of the most upstream stage 13 is connected to a stage input 121 of an amplifier input stage 12 which is positioned, in a signal processing direction, downstream of the most upstream stage 13. The stage output 122 of the stage 12 may for example be connected to other stages downstream thereof. As shown in FIG. 1, an output stage 11 is connected with a stage input 111 to one or more of the amplifier stages upstream of the output stage and is connected with a stage output 112 to an output RFout of the amplifier circuit 1. As shown in the example of FIG. 2, another terminal 114 of the output stage 11 may be connected to ground GND.

The envelope detector 100 may for instance be present in a feedforward loop or in a feedback loop. As shown in FIGS. 1 and 2, the envelope detector 100 may for example be present in a feedback loop 20 which connects the output of an electrical device to a signal input or a bias input. For instance, in the examples of FIGS. 1 and 2, the envelope detector 100 is part of a feedback loop 20 of an amplifier 10. The feedback loop 20 may connect e.g. the amplifier output RFout to the amplifier input RFin or one or more of the preceding stages 11-13. However, the feedback loop 20 may alternatively or in addition, as shown in FIGS. 1 and 2, connect the output of the amplifier 10 to a bias input 113.

As shown in FIGS. 1 and 2, the feedback loop 20 may include the envelope detector 100. Thereby, for example the envelope of the signal outputted by the amplifier 10 can be fed back, for example to at least partially reduce inter-modulation distortion and for example suppress undesired inter-modulation components generated in the amplifier 10. In this respect, it should be noted that inter-modulation distortion generally refers to a multi-frequency distortion product that results when (a) modulated signal(s) with two or more different carrier frequencies are presented at the input of a non-linear device. All electronic devices inherently exhibit a certain degree of non-linearity, even those which are biased for “linear” operation. The spurious products which are generated due to the non-linearity of a device are mathematically related to the original input signals. For sake of simplicity, in the following the input signal contains two frequencies. However it will be apparent that the input signal may include three or more frequencies. For an input signal including two frequencies f1 and f2, the frequencies of the output signal, including the inter-modulation products, can be computed by the equation:

f_{M,N}=M·f1±N·f2, where M, N=0, 1, 2, 3, . . . (1)

With f_{M,N} representing the frequency. The order of the distortion product is given by the sum of M and N. Accordingly, the second-order inter-modulation products of two signals at f1 and f2 would occur for {M=1, N=−1}, {M=−1, N=1}, and hence at f1−f2 and f2−f1. In this respect, it should be noted that the harmonic components of the input signals f1 and f2, such as 2·f1, 2·f2, 3·f1, 3·f2, etc. are not considered as intermodulation products.

Third order inter-modulation products of the two signals, f1 and f2, would be at frequencies: 2·f1+f2, 2·f1−f2, f1+2·f2, f1−2·f2. Where 2·f1 is the second harmonic of the signal at frequency f1 and 2·f2 is the second harmonic of the signal at frequency f2. Of these frequencies, only the frequencies 2·f1−f2 and 2·f2−f1 are commonly referred to as the third order inter-modulation (IMD3) products, since typically the frequencies 2·f1+f2 and f1+2·f2 are outside the carrier band. For example, for most types of modulated signals, such as amplitude modulated signals, frequency modulated signals, phase modulated signals, the spectrum of the modulated signal includes frequencies f1 and f2 which are related to each other by f1=f_{carrier}−fₑₙᵥ and f2=f_{carrier}−fₑₙᵥ where fₑₙᵥ is the envelope frequency. Typically the carrier frequency f_{carrier} is (much) larger than the envelope frequency fₑₙᵥ. Accordingly, f1 and f2 are relatively close to each other, and the third order terms 2·f1−f2 and 2·f2−f1 will be close to f1 and f2 as well. Accordingly, a regular band-pass filter will not remove the IMD3 since the IMD3 components are within the pass-band of the filter. To reduce the third order modulation, the envelope of the signal can be injected into the, non-linear, electronic device, with suitable amplitude and phase shift relative to the phase of the inter-modulation product to be reduced.

In the example of FIG. 1, the output of the amplifier 10 is connected by the feedback loop 20 to a bias input of the output stage 11 of the amplifier 10. In the feedback loop 20 the envelope detector 100 may, as shown in FIG. 1 or 2, be connected with the envelope detector output 104 to a bias control input 141 of a bias source 140. The bias source 140 is connected with a bias output to a bias input 113 of the amplifier 10. In the example of FIG. 1, for instance, the bias input 113 is connected to the output stage of the amplifier 10 and is able to provide a bias voltage (or current) to the output stage 11. The bias voltage (or current) may hence be at least partially controlled by the signal inputted at the bias control input 141. The bias source 140 may for example include a DC bias source which provides a constant bias and a variable bias source which is connected to the bias control input 141 which provides a variable bias which is superimposed on the DC bias. The bias may for example be a voltage/current bias, and as shown in FIG. 2, a ballasting resistor R1 may be present between the bias output 142 and the bias input 13 of the amplifier 10, in order to ensure thermal stability of the amplifier 10.

The envelope detector 100 may for example be connected with the input 1021 of the sensor 102 to the electrical path 14 downstream of the amplifier output RFout. The envelope detector output 104 may for example be directly or indirectly connected to an input of the amplifier output stage 11. The amplifier circuit may for instance include a bias source 140 connected to a bias input 113 of a respective stage 11-13 of the amplifier circuit 1. The bias source 140 may, as shown in FIG. 1 have a bias control input 141. At the bias control input 141 a bias control signal may be inputted which controls the amount of bias provided by the bias source 140. The bias control input 141 may for example be connected to the envelope detector output 104, and accordingly the bias may be controlled based on the envelope signal.

The amplifier circuit 1 may be used in any suitable type of device or apparatus. For instance, the amplifier 10 may be used in a wireless communication unit, for example to amplify a RF signal to an amplifier signal suitable to be transmitted by an antenna over a wireless connection. The wireless communication unit may for example include a signal generator, an amplifier circuit 1 and an antenna. The signal generator may generate a signal and transmit the generated signal to the amplifier 10. The amplifier 10 may amplify the generated signal such that the signal contains a sufficient amount of energy to be converted into an electromagnetic wave via the antenna and transmit the amplified signal to the antenna.

For instance, FIG. 3 shows a block diagram of an example of an embodiment of a wireless communication unit 200 which includes an amplifier circuit 1. The wireless communication unit 200 may comprise an antenna 201, which may for instance be connected to a duplex filter duplexer or an antenna switch 202 that provides isolation between a receiver chain 221 and a transmitter chain 220 within the wireless communication unit 200. The receiver chain 221 may include a receiver front-end circuit 203. The receiver front-end circuit 203 may for example provide a reception and/or filtering and/or intermediate or base-band frequency conversion. The receiver front-end circuit 203 may be connected, in this example via a serial coupling, to a signal processor 208, which may be implemented as a digital signal processor (DSP). An output from the signal processor 208 is provided to a suitable user interface 209, which preferably comprises an output device 211, such as a speaker and/or display, and an input device 210, such as a microphone and/or keypad.

The user interface 209 may be connected to a memory unit 206 and a timer 204, for instance via the signal processor 208 and/or a controller 205. The controller 205 may also connected to the receiver front-end circuit 203 and the signal processor 208. The controller 205 may for example receive bit error rate (BER) or frame error rate (FER) data from recovered information. The controller 205 is connected to the memory device 206 for storing operating regimes, such as decoding/encoding functions and the like. A timer 204 may be connected to the controller 205 to control the timing of operations (transmission or reception of time-dependent signals) within the wireless communication unit 200.

As regards the transmit chain 220, the input device 210 may be connected to a modulator circuit 207, for instance via the signal processor 208. The input device 210 may generate a transmit signal and transmit the signal to the modulator circuit 207. The transmit signal may be processed between generation and reception by the transmitter/modulation circuit, and for example be subjected to an analog-to-digital conversion, be converted into packets of data or other suitable processing by the signal processor 208. The transmitter/modulation circuitry 207 and receiver front-end circuitry 203 comprise frequency up-conversion and frequency down-conversion functions (not shown). The transmitter/modulation circuit 207 may modulate the transmit signal into a modulated signal and pass the, envelope modulated, transmit signal to a power amplifier 10 to be radiated from the antenna 201. The modulator circuit 207 and the power amplifier 10 are operationally responsive to the controller 205, with an output from the power amplifier 10 connected to the duplex filter or antenna switch 202. As shown in FIG. 3, the output of the power amplifier 10 may be connected to an input of an envelope detector 100. The -envelope detector 100 may be connected with the output to a control input 101 of a bias source 100, which is connected to a bias input of the power amplifier 10.

In the foregoing specification, the invention has been described with reference to specific examples of embodiments of the invention. It will, however, be evident that various modifications and changes may be made therein without departing from the broader spirit and scope of the invention as set forth in the appended claims. For example, the transistors shown in FIG. 2, may be replace with a complementary version, with, for instance, the NPN HBT may be replaced with PNP HBT and vice versa. Also, transistors of a particular type may be replace with a different type of transistors, for instance a HBT may be replaced by a MESFET or a PHEMT transistor. Also, resistors may be replaced with capacitances and inductances. Also, the amplifier circuit can be designed in a different manner, for instance by adding extra amplifier stages, e.g. in the form of transistors. Furthermore, the connections between units in the envelope detector and/or the amplifier circuit may be an type of connection suitable to transfer the signal between the units or devices. The connections may for example be direction connections or indirect connections.

Also, the invention is not limited to physical devices or units implemented in non-programmable hardware but can also be applied in programmable devices or units able to perform the desired device functions by operating in accordance with suitable program code. Furthermore, the devices may be physically distributed over a number of apparatuses, while functionally operating as a single device. For example, the envelope detector may include two or more discrete semiconductor components. E.g. the sensor 102 and the filter 103 may be implemented as separate integrated circuits.

Also, devices functionally forming separate devices may be integrated in a single physical device. For example, the amplifier circuit may for example be implemented as a single monolithic integrated circuit, for example manufactured using a RF Complementary Metal Oxide Silicon (RF CMOS), merged CMOS and bipolar (Bi-CMOS), a SiGe, or a GaAs process. However, the invention is not limited to an integrated circuit or a particular topology or a specific device technology.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the words ‘a’ and ‘an’ shall not be construed as limited to ‘only one’, but instead are used to mean ‘at least one’, and do not exclude a plurality. The mere fact that certain measures are recited in mutually different claims does not indicate that a combination of these measures cannot be used to advantage.

1. An envelope detector for detecting a modulation envelope of a modulated signal, comprising:
a sensor having a sensor input, for sensing a signal forming a measure for the amount of electrical power presented at said sensor input, which sensor input is electrically conducting connectable to an electrical path, along which electrical path said modulated signal is transmitted;
a filter for removing from the sensed signal at least a part contributed to non-envelope signal components in the modulated signal; and
a detector output connected to said filter for outputting an envelope signal.

2. An envelope detector as claimed in claim 1, wherein said sensor is a current sensor for sensing the amount of current flowing through said electrical path and said sensed signal forms a measure for said amount of current.

3. An envelope detector as claimed in claim 1, wherein the sensor includes an active electrical device for generating an image signal which forms an image of said modulated signal, which active electrical device is connected with a device input to said sensor input for sensing said modulated signal, and has a device output for outputting said image signal.

4. An envelope detector as claimed in claim 3, including a current-to-voltage converter and wherein said active electrical device includes a controllable current source which is connected with a current input to said sensor input and with a current output to said current-to-voltage converter.

5. An envelope detector as claimed in claim 3, wherein said sensor includes a sensor control input and wherein said active electrical device has an amplitude control input connected to said sensor control input, for inputting an amplitude control signal, and said active electrical device is arranged to control at least the amplitude of said image signal based on said amplitude control signal.

6. An envelope detector as claimed in claim 3, wherein said sensor includes a sensor control input, wherein said active electrical device has a controllable bias and wherein said active electrical device includes a bias input connected to said sensor control input for inputting a bias signal.

7. An envelope detector as claimed in claim 1, further including a phase shifter for shifting the phase of said envelope signal relative to said modulated signal.

8. An envelope detector as claimed in claim 1, including an network r between said sensor and a detector input, for reducing the swing of the signal inputted to said sensor.

9. An envelope detector as claimed in claim 8, wherein said network includes an RC network with a time-constant which is smaller than the inverse of the carrier frequency.

10. An envelope detector as claimed in claim 1, including a DC-Dc converter connected to said detector output for changing at least a DC level of said envelope signal.

11. A linearizer comprising an envelope detector as claimed in claim 1.

12. An electronic circuit, including:
an electronic device having an device input, and at least one device output and optionally at least one preceding stage which, in a direction of signal processing, is present upstream of the electronic device;
a feedback loop and/or a feed forward loop, said loop connecting a point in a signal path upstream or downstream of said device input to said device input, said loop including:
a linearizer as claimed in the preceding claim connected with a sensor input to said point in the signal path.

13. An electronic circuit as claimed in claim 12, wherein said electronic device is one of the group consisting of: amplifier, power amplifier, low noise amplifier, mixer, frequency multiplier, frequency up converter, frequency down converter and the like.

14. An electronic circuit as claimed in claim 12, wherein said electronic device includes an output stage and at least one preceding stage which, in a direction of signal processing, is present upstream of the output stage, and wherein said device input is an input of the output stage or of a preceding stage.

15. An electronic circuit as claimed in claim 12, further including a bias source connected to said device input, said bias source having a bias control input connected to said detector output, for controlling the bias based on the envelope signal.

16. A monolithic integrated circuit including an electronic circuit as claimed in claim 12.

17. A wireless communication unit, including:
a signal generator for generating a signal;
an electronic circuit as claimed in claim 12 for obtaining an amplified signal by amplifying said generated signal; and
an antenna for transmitting said amplified signal.

18. A method for detecting a modulation envelope of a modulated signal, including:
sensing a signal forming a measure for the amount of electrical power presented at said sensor input via an electrical conducting connection to an electrical path, along which electrical path said modulated signal is transmitted;
removing from the sensed signal at least a part contributed to non-envelope signal components in the modulated signal; and
outputting an envelope signal.

19. An envelope detector as claimed in claim 2, wherein the sensor includes an active electrical device for generating an image signal which forms an image of said modulated signal, which active electrical device is connected with a device input to said sensor input for sensing said modulated signal, and has a device output for outputting said image signal.

20. An envelope detector as claimed in claim 3, further including a phase shifter for shifting the phase of said envelope signal relative to said modulated signal.
